(19) United States
(12) Patent Application Publication
(10) Pub. No.: US 2026/0236648 A1
(43) Pub. Date: Aug. 13, 2026

(54) METHOD AND DEVICE WITH PATTERN IMAGE GENERATION

(71) Applicant: Samsung Electronics Co., Ltd., Suwon-si (KR)

(72) Inventors: Seong-Jin PARK, Suwon-si (KR); Haedong JEONG, Suwon-si (KR); Seon Min RHEE, Suwon-si (KR); Sang Chul YEO, Suwon-si (KR); Jaewon YANG, Suwon-si (KR); Seungju SHIN, Suwon-si (KR)

(73) Assignee: Samsung Electronics Co., Ltd., Suwon-si (KR)

(21) Appl. No.: 19/531,932

(22) Filed: Feb. 6, 2026

(30) Foreign Application Priority Data
Feb. 7, 2025 (KR) 10-2025-0016131

(51) Int. Cl. G06F 30/27; G06F 30/398

(52) U.S. Cl. CPC G06F 30/27; G06F 30/398

(57) ABSTRACT

A processor-implemented method includes generating marker information based on a design rule for a reference polygon, encoding the marker information into a feature vector, and generating a pattern image that includes the reference polygon by inputting the feature vector into an artificial intelligence (AI) model.

### CROSS-REFERENCE TO RELATED APPLICATIONS

This application claims priority to and the benefit under 35 USC § 119(a) of Korean Patent Application No. 10-2025-0016131 filed with the Korean Intellectual Property Office on Feb. 7, 2025, the entire disclosure of which is incorporated herein by reference for all purposes.

### BACKGROUND

### 1. Field

This disclosure relates to a method and a device for generating pattern images for manufacturing a semiconductor.

### 2. Description of Related Art

A semiconductor patterning may be a process of forming a predetermined circuit pattern on a wafer in a semiconductor manufacturing process. Typically, the semiconductor patterning may be performed through a photolithography process, an etching process, and an ion implantation process.

In the semiconductor patterning, a simulator may be used to predict how a designed pattern image is formed on the wafer when it goes through an actual semiconductor process. The semiconductor patterning simulator may predict the difference between an ideal design pattern (a layout) and the pattern that will actually be formed on the wafer by performing a simulation on the pattern images, and determine the pattern images that the current semiconductor process has vulnerabilities in. However, typical semiconductor patterning may result in an inaccurate simulation due to a low quality pattern image being used.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, a processor-implemented method may include generating marker information based on a design rule for a reference polygon, encoding the marker information into a feature vector, and generating a pattern image that may include the reference polygon by inputting the feature vector into an artificial intelligence (AI) model.

The design rule may include either one or both of a position of the reference polygon within the pattern image and a shape of the reference polygon.

The design rule may include any one or any combination of any two or more of a center coordinate, a width, a height, a vertical space, a left-right space, and a channel information of the reference polygon.

The generating of the marker information based on the design rule for the reference polygon may include generating a polygon image of the reference polygon based on the design rule, and generating a marker map by inserting a marker and channel information into the polygon image.

The generating of the marker map by inserting the marker and the channel information into the polygon image may include adding the marker to an end of a straight line that indicates a space between the reference polygon and another polygon that is adjacent to the reference polygon.

The generating of the marker map by inserting the marker and the channel information into the polygon image may include filling a color corresponding to the channel information within the reference polygon.

The generating of the marker information based on the design rule for the reference polygon may include generating a string corresponding to the reference polygon based on the design rule, and generating a marker string by inserting a marker and channel information into the string.

The generating of the string corresponding to the reference polygon based on the design rule may include adding a symbol to distinguish between numbers of coordinates of the reference polygon and numbers of a maximum space between the reference polygon and other polygons that are adjacent to the reference polygon.

The generating of the marker string by inserting the marker and the channel information into the string may include adding a color code of a color corresponding to the channel information to the string.

The encoding the marker information into the feature vector may include inserting a positional encoding for the marker information into the marker string.

In one or more general aspects, an apparatus includes one or more processors comprising processing circuitry, and memory comprising one or more storage media storing instructions that, when executed individually or collectively by the one or more processors, cause the apparatus to generate marker information based on a design rule regarding one or more reference polygons to be included in a pattern image, encode the marker information into a feature vector, and generate, by inputting the feature vector into an artificial intelligence (AI) model as input data, a plurality of pattern images including the reference polygon generated from a noise image and the input data.

For the encoding of the marker information into the feature vector and inputting the feature vector into the AI model, the execution of the instructions may cause the apparatus to input the feature vector to a last convolution block and/or a penultimate convolution block in the AI model.

For the generating of the marker information based on the design rule for the reference polygon, the execution of the instructions may cause the apparatus to generate a polygon image of the reference polygon based on the design rule, and generate a marker map by inserting a marker and channel information into the polygon image.

For the generating of the marker map by inserting the marker and the channel information into the polygon image, the execution of the instructions may cause the apparatus to add the marker to an end of a straight line that indicates a space between the reference polygon and another polygon that is adjacent to the reference polygon.

For the generating of the marker map by inserting the marker and the channel information into the polygon image, the execution of the instructions may cause the apparatus to fill a color corresponding to the channel information within the reference polygon.

For the generating of the marker information based on the design rule regarding the one or more reference polygons to be included in the pattern image, the execution of the instructions may cause the apparatus to generate a string corresponding to the reference polygon based on the design rule, and generate a marker string by inserting a marker and channel information into the string.

For the generating of the string corresponding to the reference polygon based on the design rule, the execution of the instructions may cause the apparatus to add a symbol to distinguish between numbers of coordinates of the reference polygon and numbers of a maximum space between the reference polygon and other polygons that are adjacent to the reference polygon.

The execution of the instructions may cause the apparatus to determine, from among the plurality of pattern images, one or more pattern images having a relatively high likelihood of resulting in a defective circuit pattern through a semiconductor manufacturing process.

In one or more general aspects, an apparatus includes one or more processors comprising processing circuitry, and memory comprising one or more storage media storing instructions that, when executed individually or collectively by the one or more processors, cause the apparatus to perform a simulation on a circuit pattern using a plurality of pattern images generated based on a design rule for a reference polygon, and determine, from among the plurality of pattern images, one or more pattern images based on a result of the performing of the simulation, wherein the one or more pattern images have a relatively high likelihood of resulting in a defective circuit pattern through a semiconductor manufacturing process.

The execution of the instructions may cause the apparatus to generate the plurality of pattern images by inputting a feature vector to an artificial intelligence (AI) model, wherein the feature vector is encoded from a marker map generated based on a design rule regarding the reference polygons to be included in the plurality of pattern images, and generating, using the AI model, the plurality of pattern images including the reference polygon from a noise image.

Other features and aspects will be apparent from the following detailed description, the drawings, and the claims.

### BRIEF DESCRIPTION OF THE DRAWINGS

FIG. 1A illustrates a simulation system for a semiconductor process development according to one or more embodiments.

FIG. 1B illustrates a pattern image input to a simulator according to one or more embodiments.

FIG. 2 illustrates a pattern image generating device according to one or more embodiments.

FIG. 3 illustrates a method for generating a pattern image according to one or more embodiments.

FIG. 4 illustrates a structure of an encoder and an AI model according to one or more embodiments.

FIG. 5 illustrates a method for generating a marker map by a marker information generator according to one or more embodiments.

FIG. 6 illustrates a marker map generated by a marker information generator according to one or more embodiments.

FIG. 7A and FIG. 7B illustrate pattern images including a marker map according to one or more embodiments.

FIG. 8 illustrates a method for generating a marker string by a marker information generator according to one or more embodiments.

FIG. 9 illustrates a neural network according to one or more embodiments.

FIG. 10 illustrates a pattern image generating apparatus according to one or more embodiments.

Throughout the drawings and the detailed description, unless otherwise described or provided, the same drawing reference numerals may be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example”, “embodiment”, and “example embodiment” herein have a same meaning (e.g., the phrasing ‘in an or one example’ has a same meaning as ‘in an or one embodiment” and ‘in an or one example embodiment’), and “one or more examples” has a same meaning as “one or more embodiments” and “one or more example embodiments”. Still further, each of multiple or all separately described an/one “example”, “embodiment”, “example embodiment”, as well as “examples”, “embodiments”, “example embodiments”, herein may be included, in combination, in a same embodiment in any combination.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C” (e.g., each phrase may include any one of the respective items alone, all of the items listed together, and all possible combinations thereof), and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

An artificial intelligence (AI) model of the present disclosure may be a machine learning model that learns at least one task, and may be implemented as a computer program executed by a processor. The task that the AI model learns may refer to a task to be solved through machine learning or a task to be executed through machine learning. The AI model may be implemented as a computer program executed on a computing apparatus, may be downloaded through a network, or may be sold as a product. Alternatively or additionally, the AI model may be networked with a variety of apparatuses.

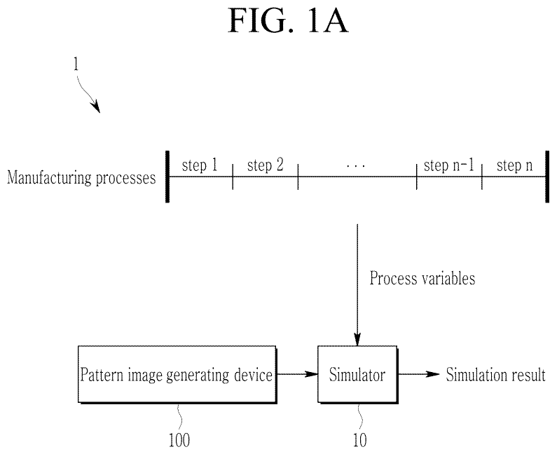

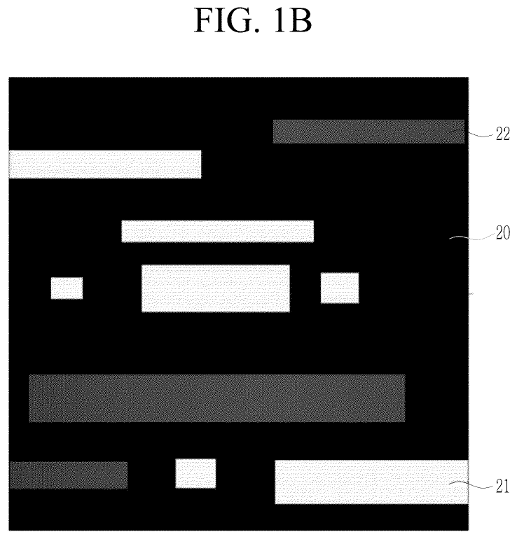

FIG. 1A illustrates a simulation system for a semiconductor process development according to one or more embodiments. FIG. 1B illustrates a pattern image input to a simulator according to one or more embodiments.

By securing a high quality pattern image, a method and apparatus of one or more embodiments may increase an accuracy of a semiconductor patterning simulation. Referring to FIG. 1A, a simulation system 1 according to one or more embodiments may simulate a circuit pattern to be formed on a semiconductor wafer by a pattern image (e.g., a pattern cast) applied in a semiconductor manufacturing process by using a simulator 10. That is, the simulation system 1 may be used to verify process variables of the semiconductor manufacturing process through the simulation results of the circuit pattern and to develop a valid semiconductor process. The simulation results for the circuit pattern may be analyzed to adjust the process variables of the semiconductor manufacturing processes. Further, the simulation results for the circuit pattern may determine a score of a pattern image which indicates likelihood and/or probability of resulting in a defective circuit pattern through the manufacturing process.

In some embodiments, the simulator 10 may output the simulated circuit pattern (e.g., the simulation result) corresponding to the pattern image input based on the process variables of the manufacturing processes, and may determine at least one pattern image having a relatively high likelihood (e.g., having a greatest likelihood and/or probability) of resulting in a defective circuit pattern through the manufacturing process from among the several pattern images based on the simulation result.

In some embodiments, the process variables may be physical and chemical elements that can affect the formation of the circuit pattern. The photolithography process may include the process variables such as an exposure wavelength (e.g., ArF, EUV, etc.), a light intensity, a defocus (e.g., DOF) error, physical characteristics of a photoresist (e.g., photoresist thickness, sensitivity, etc.), and an optical proximity correction (OPC). The etching process may include the process variables such as kinds (e.g., CF4, SF6, Cl2, etc.) of a plasma gas, an etching time (e.g., an over-etching, an under-etch, etc.), an etching selectivity, an anisotropy (e.g., an etching ratio of a vertical direction to a horizontal direction), and the like. The deposition process may include the process variables such as deposition methods (e.g., CVD, ALD, PVD, etc.), deposition temperatures, and plasma conditions (e.g., a plasma pressure, an intensity, etc.). The ion implantation process may include the process variables such as an ion type (e.g., boron, phosphorus, arsenic, etc.), an implant energy (e.g., an ion energy), and an implant dose (e.g., a dose). The thermal process (e.g., an annealing) may include the process variables such as a temperature, a time, and a method (e.g., a rapid thermal annealing, a furnace annealing, etc.). The metal Interconnect process may include the process variables such as a doping concentration and a presence or absence of a rear layer.

In general, a greater diversity and a greater generation efficiency in the pattern image may improve the accuracy in detecting the boundary condition (a patterning error) of the simulator 10. The pattern images may be typically generated either directly by humans (e.g., a manufacturer) or through rule-based methods. When a manufacturer generates the pattern image, there may a deviation in the quality of the pattern image generated depending on the manufacturer's expertise, which may reduce the diversity and slow down the generation speed. For the rule-based methods, there is a limit to the diversity that the pattern image may have depending on the complexity of the rule, and an accuracy and a fidelity are generally low.

In some embodiments, the pattern image within a pattern image group may be input to the simulator 10. Referring to FIG. 1A, a pattern image generating device 100 may generate a plurality of pattern images and store the plurality of pattern images as a pattern image group.

In some embodiments, the pattern image for simulating the manufacturing process of the semiconductor may have a predetermined size and include a plurality of polygons. Each polygon in the pattern image may be a polygon shape used in semiconductor layout design and may correspond to an electrical connection or a circuit element within the semiconductor circuit. For example, the polygon may represent a metal routing, a gate, and/or a contact.

Referring to FIG. 1B, a first polygon 21 filled with white color in the pattern image may be a polygon of a first channel (e.g., channel information 0), and a second polygon 22 filled with gray color in the pattern image may be a polygon of a second channel (e.g., channel information 1). Here, the channel may be one of a plurality of pattern channels used for a multi-patterning.

In some embodiments, the layout and shape of the polygons may be determined by a design rule of the circuit pattern. The design rule may determine the layout and shape of each polygon within the pattern image. The design rule may include physical references, such as the positions (e.g., coordinates) of the polygons within the pattern image, the space between the polygons, dimensions of the polygons, etc. For example, Table 1 below is a design rule representing the layout and shape of the first polygon 21.

TABLE 1

| Center | Center | | | Upper | Lower | Right | Left | Channel |
|---|---|---|---|---|---|---|---|---|
| Coord. X | Coord. Y | Width | Height | space | space | space | space | information |
| 100 | 100 | 50 | 15 | 12 | 10 | 0 | 15 | 0 |

In some embodiments, the pattern image generating device 100 of one or more embodiments may generate the pattern image with a high efficiency and increase the diversity of the pattern image by using a generative AI model based on the design rule of the polygon. Hereinafter, examples of the method for generating the pattern image for simulating the semiconductor manufacturing process by using the generative AI model based on the polygon design rule through the pattern image generating device 100 are specifically described.

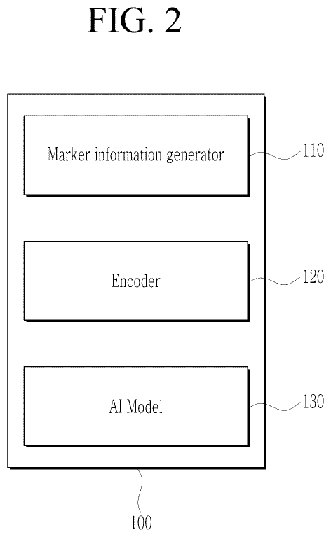

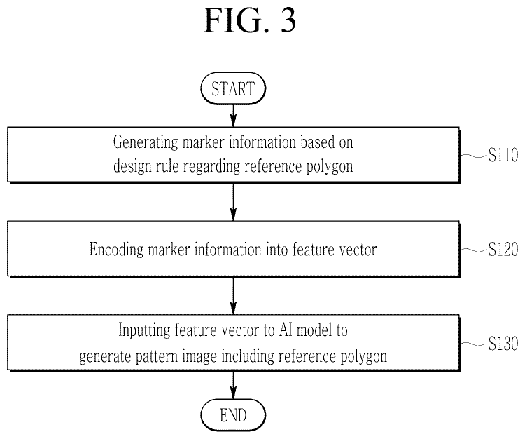

FIG. 2 illustrates a pattern image generating device according to one or more embodiments. FIG. 3 illustrates a method for generating a pattern image according to one or more embodiments.

Referring to FIG. 2, a pattern image generating device 100 according to one or more embodiments may include a marker information generator 110, an encoder 120, and an AI model 130.

Referring to FIG. 2 and FIG. 3, in operation S110, the marker information generator 110 may generate marker information based on a design rule regarding at least one reference polygon to be included in a pattern image. The reference polygon may be determined in advance to be arranged at the center or around the center of the pattern image.

In some embodiments, in operation S110, the marker information generator 110 may generate a marker map including markers as marker information based on the design rule regarding at least one reference polygon. Alternatively or additionally, the marker information generator 110 may generate a marker string including position information of the marker as marker information based on the design rule regarding at least one reference polygon.

Referring to FIG. 2 and FIG. 3, in operation S120, the encoder 120 may encode the marker information into a feature vector. In some embodiments, the encoder 120 may encode the marker map generated from the design rule of the reference polygon into a feature vector. Alternatively or additionally, the encoder 120 may encode the marker string generated from the design rule of the reference polygon into another feature vector.

In some embodiments, the feature vector encoded by the encoder 120 may correspond to a respective polygon. For example, in operation S120, when the design rule determines the layout and shape of a plurality of reference polygons within the pattern image, the encoder 120 may encode a plurality of feature vectors each corresponding to a respective one of the plurality of reference polygons.

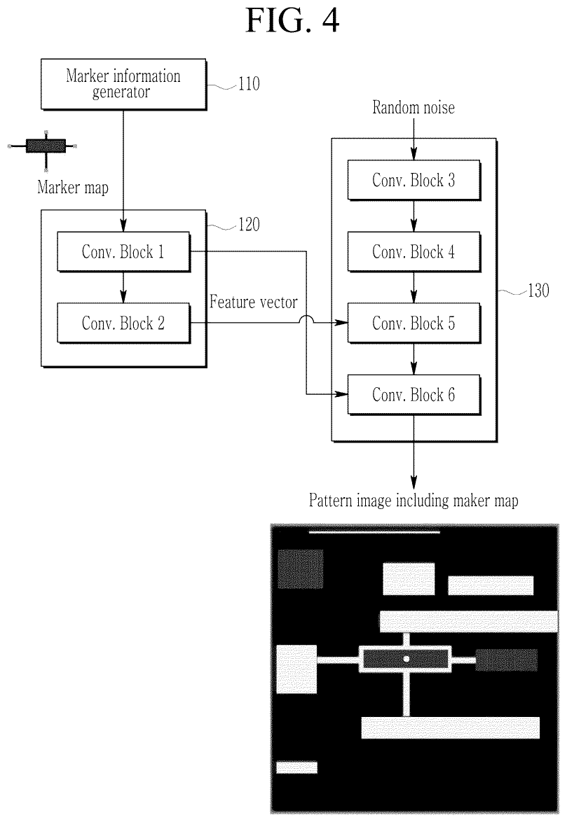

FIG. 4 illustrates a structure of an encoder and an AI model according to one or more embodiments.

Referring to FIG. 4, a marker information generator 110 according to one or more embodiments may generate a marker map as marker information and transmit the marker map to an encoder 120.

In some embodiments, at least one convolution block among a plurality of convolution blocks included in and/or implemented by the encoder 120 may output a feature vector corresponding to a marker map. The feature vector output from the encoder 120 may be transmitted to the AI model 130.

In some embodiments, the feature vector may be transmitted to any block (e.g., convolution blocks) of the AI model 130. Referring to FIG. 4, the feature vector output from the convolution block 1 of the encoder 120 may be transmitted to the convolution block 6 (e.g., the last convolution block) of the AI model 130, and the feature vector output from the convolution block 2 of the encoder 120 may be transmitted to the convolution block 5 (e.g., the penultimate convolution block) of the AI model 130 (e.g., a cross attention). In this example, the feature vector output from the convolution block 1 of the encoder 120 and the feature vector output from the convolution block 2 of the encoder 120 may be different.

In this way, as the feature vector of the marker map generated by the encoder 120 is transmitted to the last function block (e.g., the convolution block) and/or the penultimate function block in the AI model 130, it may be ensured that the marker map is included in the pattern image generated by the AI model 130. In addition, by transmitting two or more feature vectors from the encoder 120 to the different function blocks of the AI model 130, it may be further ensured that the marker map is included in the pattern image generated by the AI model 130.

Referring to FIG. 2 and FIG. 3, in operation S130, the AI model 130 may receive at least one feature vector corresponding to at least one reference polygon from the encoder 120, and generate the pattern image including the reference polygon from a noise image including random noise (e.g., Gaussian noise following a normal distribution).

In some embodiments, the AI model 130 may use a generative neural network structure such as a diffusion model or a generative adversarial network (GAN) to generate images belonging to the domain of the trained image from the noise image.

For example, when the AI model 130 uses the structure of the diffusion model, the AI model 130 may be trained by adding noise to a training image according to a predetermined noise schedule to generate a noise-added image, predicting a noise component added to the noise-added image, and then minimizing a loss function representing a difference between the added noise component and the predicted noise component.

For example, when the AI model 130 uses a structure of a GAN, the AI model 130 may be trained by generating an image similar to the training image from the noise image using a generator of the GAN and determining whether the image generated by the generator belongs to the domain of the training image using a discriminator of the GAN.

In some embodiments, the AI model 130 trained based on existing pattern images of the semiconductor may then generate a new pattern image belonging to the domain of the existing pattern images from the noise image. That is, since the AI model 130 is trained using the existing pattern images of the semiconductor, the new pattern image generated by the trained AI model 130 may include the polygons of the same or similar shape as the polygons in the existing pattern images. For example, when the polygon is usually a convex polygon, not a triangle, and even when it is the concave polygon, the polygon may not include an interior angle that is acute (e.g., an angle less than 90 degrees).

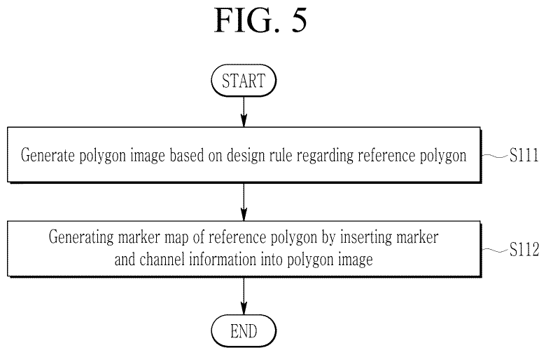

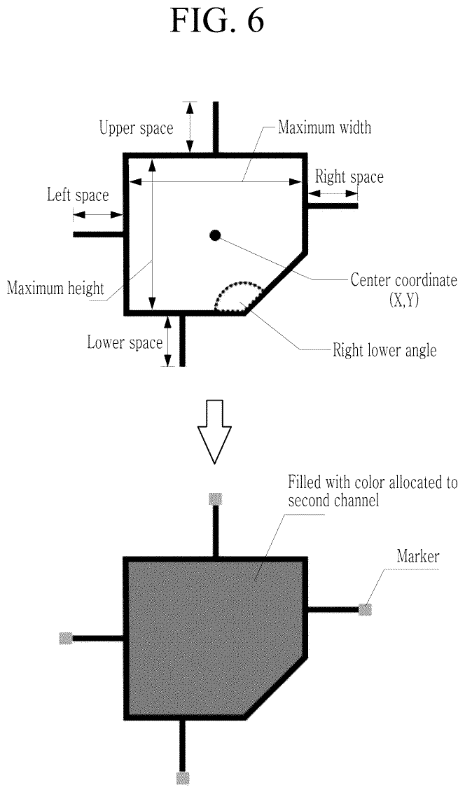

FIG. 5 illustrates a method for generating a marker map by a marker information generator according to one or more embodiments. FIG. 6 illustrates a marker map generated by a marker information generator according to one or more embodiments.

Referring to FIG. 5, in operation S111, a marker information generator 110 may generate a polygon image based on a design rule regarding a reference polygon. For example, the marker information generator 110 may convert the design rule such as Table 2 below into the polygon image.

TABLE 2

| Center | Center | Max. | Max. | Upper | Lower | Right | Left | Right | Channel |
|---|---|---|---|---|---|---|---|---|---|
| Coord. X | Coord. Y | width | Height | space | space | space | space | lower angle | information |
| 60 | 60 | 40 | 35 | 20 | 20 | 20 | 20 | 140 | 1 |

Referring to FIG. 6, the design rule of the reference polygon may be used to generate a convex pentagon, and the reference polygon may be positioned at the center of the pattern image with a pixel size of 120×120. In FIG. 6, four straight lines extending from the reference polygon in the outward direction of the polygon represent maximum spaces between the reference polygon and the other neighboring polygon.

Referring to FIG. 5, in operation S112, the marker information generator 110 may generate the marker map by inserting the marker and the channel information into the polygon image.

In some embodiments, in operation S112, the marker information generator 110 may add the marker at the end of the straight line that indicate the maximum space between the polygons. In some embodiments, the marker may ensure that no other adjacent polygon within the pattern image generated by the AI model 130 is located within the spacing of the design rule of the reference polygon. Additionally, the marker may ensure that another adjacent polygon is positioned at the space of the design rule of the reference polygon in the pattern image generated by the AI model 130.

In some embodiments, in operation S112, the marker information generator 110 may fill a color corresponding to the channel information within the reference polygon. Referring to FIG. 6, according to the design rule of Table 2, the gray color of the second channel corresponding to the channel information 1 is allocated to the reference polygon. Any color may be filled to each channel, and in another embodiment a color other than gray color may be allocated to the second channel.

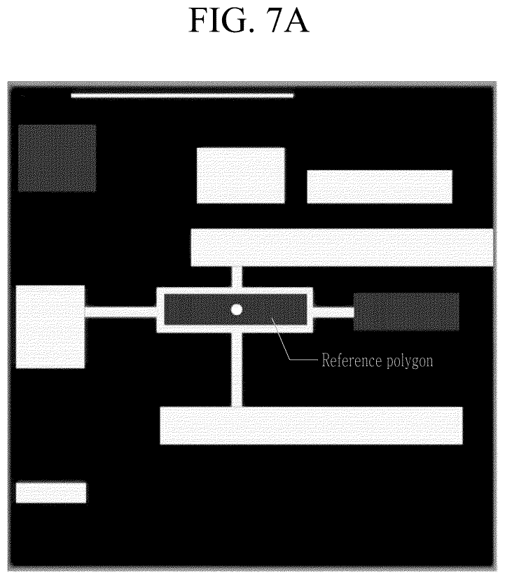

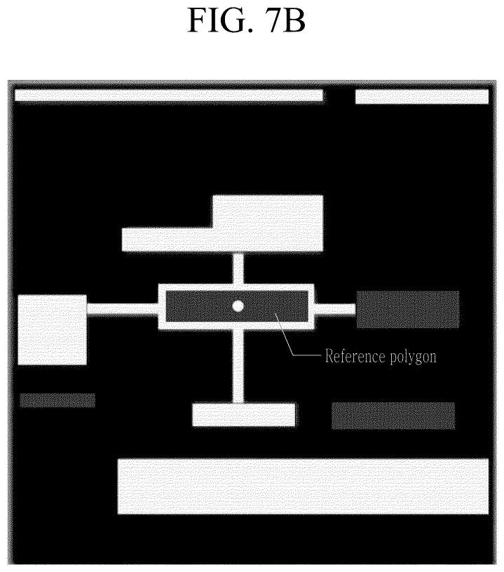

FIG. 7A and FIG. 7B illustrate pattern images including a marker map according to one or more embodiments.

Referring to FIG. 7A and FIG. 7B, a reference polygon according to a design rule is positioned at the center of the pattern image, and polygons generated by the AI model 130 are positioned around the reference polygon. In FIG. 7A and FIG. 7B, the boundary of the reference polygon is indicated by a white border, and the space between the reference polygon and other adjacent polygons is indicated by a white bar.

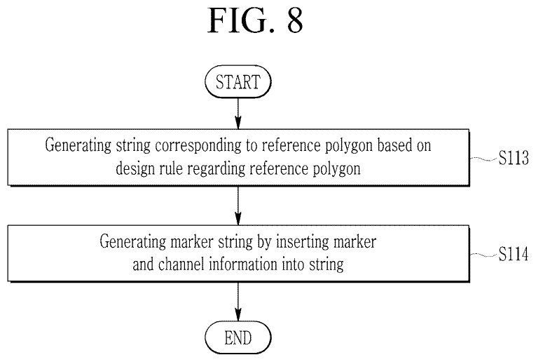

FIG. 8 illustrates a method for generating a marker string by a marker information generator according to one or more embodiments.

Referring to FIG. 8, in operation S113, the marker information generator 110 may generate a string corresponding to the reference polygon based on the design rule regarding the reference polygon. The marker information generator 110 may explicitly distinguish numbers and/or contents of the design rule for the reference polygon within the string. For example, numbers of the coordinates of the reference polygon and number of the space between the reference polygon and another polygon to be adjacent to the reference polygon may be distinguished from each other by arbitrary symbols or other means, or by the position of the numbers or contents within the string.

Referring to FIG. 8, in operation S114, the marker information generator 110 may generate a marker string by inserting a marker and channel information into the string generated from the design rule for the reference polygon. For example, the marker information generator 110 may insert the marker by adding a symbol to distinguish numbers of the space between the reference polygon and another neighboring polygon in the string. Alternatively or additionally, the marker information generator 110 may insert the channel information by adding a color code of the color corresponding to the channel information into the string generated from the design rule for the reference polygon.

When the encoder 120 encodes the marker string into a feature vector, the encoder 120 may insert a positional embedding for the marker information into the marker string (e.g., a positional encoding on the marker string), thereby ensuring that the characteristic of the marker inserted into the number regarding the space of the reference polygon is maintained in the feature vector.

In FIG. 8, the method is described in which the marker information generator 110 generates the marker string including the position information of the marker as the marker information based on the design rule for the reference polygon, but the marker information generator 110 may generate one of the marker map or the marker string as the marker information, may not generate both of the marker map and the marker string as the marker information, and does not limited thereto.

As described above, the pattern image generating device 100 of one or more embodiments may quickly and efficiently generate various high-quality semiconductor pattern images by using the AI models based on the design rules of the reference polygon. Accordingly, the various high-quality semiconductor pattern images enable the semiconductor process simulation system of one or more embodiments to accurately determine the pattern images that have vulnerabilities in the designed process.

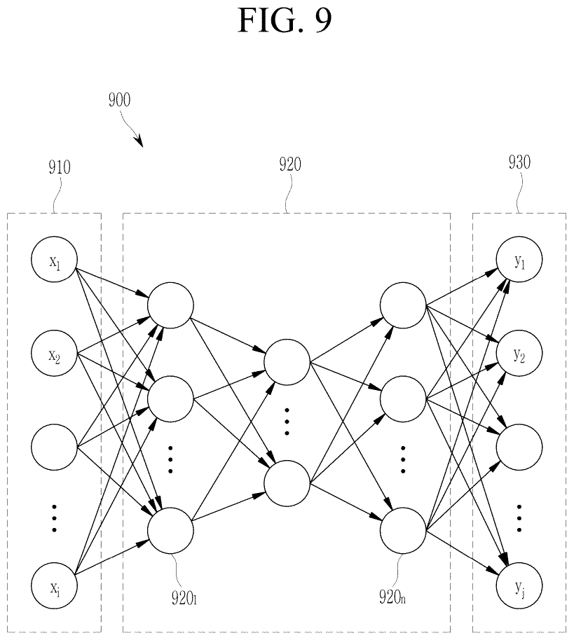

FIG. 9 illustrates a neural network according to one or more embodiments.

Referring to FIG. 9, an neural network (NN) 900 according to one or more embodiments may include an input layer 910, a hidden layer 920, and an output layer 930. The neural network 900 may have an encoder-decoder structure and may constitute a part and/or all of the generative AI model that generates the images belonging to the domain of the training images from the noise image as described above.

The input layer 910, the hidden layer 920, and the output layer 930 each include a plurality of nodes, and the strength of each connection between the nodes may correspond to a weight value (e.g., a weight connection). The plurality of nodes included in the input layer 910, the hidden layer 920, and the output layer 930 may be fully connected to each other. In some embodiments, the number of parameters (e.g., weight values and biases) may be equal to the number of weight value connections in the neural network 900.

The input layer 910 may include a plurality of input nodes (e.g., x₁ to xᵢ), and the number of the input nodes (e.g., x₁ to xᵢ) may correspond to the number of independent variables of the input data. For training the neural network 900, an original dataset and/or an augmented dataset may be input to the input layer 910. When an inference target data is input to the input layer 910 of the trained neural network 900, an inference result may be output from the output layer 930 of the trained neural network 900. In some embodiments, the input layer 910 may have a structure suitable for processing large inputs.

The hidden layer 920 may be positioned between the input layer 910 and the output layer 930, and may include at least one hidden layer (e.g., 920₁ to 920ₙ). The output layer 930 may include at least one output node (e.g., y₁ to yⱼ). An activation functions may be used in the hidden layer 920 and the output layer 930. In some embodiments, the neural network 900 may be trained by adjusting the parameters of the hidden nodes included in the hidden layer 920.

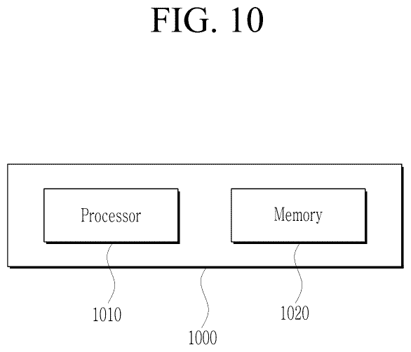

FIG. 10 illustrates a pattern image generating apparatus according to one or more embodiments.

A pattern image generating apparatus according to one or more embodiments may be implemented as a computer system, for example, as a computer-readable medium. Referring to FIG. 10, a computer system 1000 includes one or more processors 1010 and a memory 1020 (e.g., one or more memories). The memory 1020 may be connected to the one or more processors 1010 and store various information for operating the one or more processors 1010 or at least one program to be executed by the one or more processors 1010. Alternatively or additionally, the memory 1020 may store instructions configured to cause the one or more processors 1010 to perform functions, processes, or methods described in one or more embodiments. For example, the memory 1020 may be or include a non-transitory computer-readable storage medium storing instructions that, when executed by the one or more processors 1010, configure the one or more processors 1010 to perform any one, any combination, or all of the operations and/or methods disclosed herein with reference to FIGS. 1-10.

The one or more processors 1010 may implement the functions, processes, or methods suggested in one or more embodiments. The operation of the computer system 1000 according to one or more embodiments may be implemented by the one or more processors 1010. The one or more processors 1010 may include at least one of a GPU, a CPU, and an NPU. When the operation of the computer system 1000 may be implemented by the one or more processors 1010, each work may be divided among the one or more processors 1010 according to a load or cost. For example, when one processor is the CPU, another processor may be any of the GPU, NPU, FPGA, or DSP. The one or more processors 1010 may include and/or implement the marker information generator 110, the encoder 120, and/or the AI model 130 of FIG. 2.

In the example of the present disclosure, the memory 1020 may be positioned internally or externally to the processor, and the memory may be connected to the processor via a variety of known means. The memory is various types of storage medium that may be volatile or non-volatile. For example, the memory may include a read-only memory (ROM) or a random access memory (RAM).

In the present disclosure, some functions of the lithography network may be provided by a neuromorphic chip including a connection module between a synapse and a neuron. The neuromorphic chip may be a computer apparatus that simulates a structure of a biological nervous system, and may perform a neural network task.

The electronic devices and apparatuses, processors, memories, marker information generators, encoders, computer systems, simulators, pattern image generating devices, simulator 10, pattern image generating device 100, processor 1010, memory 1020, marker information generator 110, encoder 120, and computer system 1000 described herein, including descriptions with respect to respect to FIGS. 1-10, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-10 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. Thus, references herein to storage media mean storage media hardware, and does not mean to transitory media, nor a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method comprising:
generating marker information based on a design rule for a reference polygon;
encoding the marker information into a feature vector; and
generating a pattern image that includes the reference polygon by inputting the feature vector into an artificial intelligence (AI) model.

2. The method of claim 1, wherein the design rule includes either one or both of a position of the reference polygon within the pattern image and a shape of the reference polygon.

3. The method of claim 1, wherein the design rule includes any one or any combination of any two or more of a center coordinate, a width, a height, a vertical space, a left-right space, and a channel information of the reference polygon.

4. The method of claim 1, wherein the generating of the marker information based on the design rule for the reference polygon includes:
generating a polygon image of the reference polygon based on the design rule; and
generating a marker map by inserting a marker and channel information into the polygon image.

5. The method of claim 4, wherein the generating of the marker map by inserting the marker and the channel information into the polygon image includes adding the marker to an end of a straight line that indicates a space between the reference polygon and another polygon that is adjacent to the reference polygon.

6. The method of claim 4, wherein the generating of the marker map by inserting the marker and the channel information into the polygon image includes filling a color corresponding to the channel information within the reference polygon.

7. The method of claim 1, wherein the generating of the marker information based on the design rule for the reference polygon includes:
generating a string corresponding to the reference polygon based on the design rule; and
generating a marker string by inserting a marker and channel information into the string.

8. The method of claim 7, wherein the generating of the string corresponding to the reference polygon based on the design rule includes adding a symbol to distinguish between numbers of coordinates of the reference polygon and numbers of a maximum space between the reference polygon and other polygons that are adjacent to the reference polygon.

9. The method of claim 7, wherein the generating of the marker string by inserting the marker and the channel information into the string includes adding a color code of a color corresponding to the channel information to the string.

10. The method of claim 7, wherein the encoding the marker information into the feature vector includes inserting a positional encoding for the marker information into the marker string.

11. An apparatus comprising:
one or more processors comprising processing circuitry; and
memory comprising one or more storage media storing instructions that, when executed individually or collectively by the one or more processors, cause the apparatus to:
generate marker information based on a design rule regarding one or more reference polygons to be included in a pattern image;
encode the marker information into a feature vector; and
generate, by inputting the feature vector into an artificial intelligence (AI) model as input data, a plurality of pattern images including the reference polygon generated from a noise image and the input data.

12. The apparatus of claim 11, wherein, for the encoding of the marker information into the feature vector and inputting the feature vector into the AI model, the execution of the instructions causes the apparatus to input the feature vector to a last convolution block and/or a penultimate convolution block in the AI model.

13. The apparatus of claim 11, wherein, for the generating of the marker information based on the design rule for the reference polygon, the execution of the instructions causes the apparatus to:
generate a polygon image of the reference polygon based on the design rule; and
generate a marker map by inserting a marker and channel information into the polygon image.

14. The apparatus of claim 13, wherein, for the generating of the marker map by inserting the marker and the channel information into the polygon image, the execution of the instructions causes the apparatus to add the marker to an end of a straight line that indicates a space between the reference polygon and another polygon that is adjacent to the reference polygon.

15. The apparatus of claim 13, wherein, for the generating of the marker map by inserting the marker and the channel information into the polygon image, the execution of the instructions causes the apparatus to fill a color corresponding to the channel information within the reference polygon.

16. The apparatus of claim 11, wherein, for the generating of the marker information based on the design rule regarding the one or more reference polygons to be included in the pattern image, the execution of the instructions causes the apparatus to:
generate a string corresponding to the reference polygon based on the design rule; and
generate a marker string by inserting a marker and channel information into the string.

17. The apparatus of claim 16, wherein, for the generating of the string corresponding to the reference polygon based on the design rule, the execution of the instructions causes the apparatus to add a symbol to distinguish between numbers of coordinates of the reference polygon and numbers of a maximum space between the reference polygon and other polygons that are adjacent to the reference polygon.

18. The apparatus of claim 11, wherein the execution of the instructions causes the apparatus to determine, from among the plurality of pattern images, one or more pattern images having a relatively high likelihood of resulting in a defective circuit pattern through a semiconductor manufacturing process.

19. An apparatus comprising:
one or more processors comprising processing circuitry; and
memory comprising one or more storage media storing instructions that, when executed individually or collectively by the one or more processors, cause the apparatus to:
perform a simulation on a circuit pattern using a plurality of pattern images generated based on a design rule for a reference polygon; and
determine, from among the plurality of pattern images, one or more pattern images based on a result of the performing of the simulation,
wherein the one or more pattern images have a relatively high likelihood of resulting in a defective circuit pattern through a semiconductor manufacturing process.

20. The apparatus of claim 19, wherein the execution of the instructions causes the apparatus to generate the plurality of pattern images by:
inputting a feature vector to an artificial intelligence (AI) model, wherein the feature vector is encoded from a marker map generated based on a design rule regarding the reference polygons to be included in the plurality of pattern images; and
generating, using the AI model, the plurality of pattern images including the reference polygon from a noise image.
